(19) United States
(12) Patent Application Publication
(10) Pub. No.: US 2003/0118727 A1
(43) Pub. Date: Jun. 26, 2003

(54) Method for fabrication of carbon nanotubes having multiple junctions

(76) Inventors: Jyh-Ming Ting, Tainan City (TW); Chi-Chih Chang, Tainan City (TW)

Correspondence Address: WILDMAN, HARROLD, ALLEN & DIXON, 225 WEST WACKER DRIVE, CHICAGO, IL, 60606, US

(21) Appl. No.: 10/292,552

(22) Filed: Nov. 12, 2002

(30) Foreign Application Priority Data
Dec. 25, 2001 (TW) 90132118

(51) Int. Cl. C23C 16/26

(52) U.S. Cl. 427/249.1

(57) ABSTRACT

A method for fabricating carbon nanotubes having multiple junctions, comprising the process of supplying at least a substrate, metal powders, and carbon-containing reactant gas to chemical vapor deposition (CVD) system under high temperature. Carbon nanotubes having multiple junctions form above the substrate, thereby exhibiting two-dimensional and/or three-dimensional web-like structures with uniform diameters.

### BACKGROUND OF THE INVENTION

1. Field of the Invention

This invention relates to a method for fabricating carbon nanotubes having multiple junctions. More specifically, the invention relates to the use of thermal chemical vapor deposition (thermal CVD) without any template; a process for forming carbon nanotubes with two-dimensional (2D) structures such as H-junction, multiple Y-junctions, and three-dimensional (3D) multiple junctions. The result leads to a new class of carbon nanotube materials.

2. Description of the Prior Art

Carbon nanotubes were first reported in 1991 by S. Iijima and have emerged as one of the primary research topics in the field. Carbon nanotubes are tabular structures formed by one or more layers of unsaturated graphene. They exhibit exceptional electrical, magnetic, and light properties with unlimited potential for applications such as optic-electronic devices, electronic devices, biomedical science, energy resource. etc. For example, a single carbon nanotube can be used in high resolution electron beam devices, for example by placing it on the tip of an atomic force microscope, or used in field-effect transistors as electron passages between metal poles. Furthermore, bundles of carbon nanotubes can be used in flat panel displays; for example, Samsung has successfully developed a 4.5 inch full color flat panel display.

Basically, the graphene structure and chemical properties of carbon nanotubes are fairly similar to Carbon-60 (C₆₀). Currently, there are three methods for fabricating carbon nanotubes:

The first method is called plasma discharging, which forms carbon nanotubes by electrical sparks under conditions where two graphene rods are placed in a direct-current electric field in the presence of inert gases such as He or Ar.

The second method uses the laser ablation procedure, which produces carbon nanotubes by directing a high-energy laser at graphene rods under 1200° C. temperature.

The third method creates carbon nanotubes by using the metal catalyzed thermal CVD method with iron, cobalt, nickel powders and pyrolysis of methane and acetylene in a high temperature furnace with operating temperature above 700° C.

Given the unique properties of carbon nanotubes, they can be used in a wide range of molecular-scale or nano-scale devices. In the case of nano-scale device, one has to consider the problem of creating 2D and 3D junctions. One way to create such junctions is to place carbon nanotubes across patterned metals, which requires very sophisticated manipulation [“Room—temperature transistor based on a single carbon nanotube”, Nature, 393, 49-52 (1998)]. Another approach is through the formation of branching nanotubes during growth. The first observed branching nanotube demonstrates the formation of L-junction, Y-junction, and T-junction through an arc-discharge method. The nanotube has a diameter in the order of 10¹ nm [“Complex branching in the growth of carbon nanotubes”, Chem. Phys. Lett., 238, 286-289 (1995)]. However, the formation of these different junctions is totally random. A single branching pattern of Y-junction carbon nanotubes can be obtained using either the hot filament CVD method [“Branching carbon nanotubes deposited in HFCVD system”, Diamond and Related Materials, 9, 897-900 (2000)] or pyrolysis of nickelocene along with thiophene [“Y-junction, carbon nanotubes”, Appl. Phys. Lett., 77, 2530-2532 (2000)]. These methods provide carbon nanotubes diameters ranging from 15 nm to 100 nm.

In addition, the so-called nanochannel alumina (NCA) method has been used to grow carbon nanotubes with Y-junction. Such carbon nanotubes has been determined to be capable of electron transport and has a diameter ranging from 35 nm to 60 nm [“Growing Y-junction carbon nanotubes”, Nature, 402, 253-254 (1999)]. Furthermore, CVD has been used to form Y-junction as well. However, these methods require the use of templates in order to form junctions.

All the above methods enable the growth of junctions limited to 2D structures or involve at most three-way junctions. For future mechanical, electrical and biological applications, multiple-way junctions or 3D junctions will be required.

### SUMMARY OF THE INVENTION

In light of the disadvantages and limits of current carbon nanotube fabrication, this invention provides a method for fabricating carbon nanotubes having multiple junctions of 2D and/or 3D structures at the same time.

Using a simple thermal CVD method without any template, this invention enables the fabrication of 2D (such as H-junction) and 3D branching structures of carbon nanotubes. The method comprises of supplying at least a substrate, metal powders, and carbon-containing reactant gas to chemical vapor deposition system under high temperature. Carbon nanotubes with multiple junctions form above the substrate demonstrating 2D and/or 3D branching structures of uniform diameters.

The chemical vapor deposition system mentioned above is a thermal vapor deposition system (thermal CVD).

There is no restriction as to the type of substrate that may be used in this invention; however, silicon, especially single-crystalline silicon, is suitable for the growth of carbon nanotubes.

Evaporation-deposition method or similar methods can be used to seed metal powders on the substrate, forming nano-scale catalysts. The metal is either a type of transition metal or its alloy. Suitable transition metals are: iron, cobalt, nickel, platinum, palladium, and/or compounds of these metals, and/or alloys thereof. In particular, iron is well suited for the purpose.

The carbon-containing reactant gas is composed of hydrocarbons. Methane, ethylene, propane, acetylene, or mixtures thereof are all suitable reactant gases. Among these gases, methane is the preferred choice.

The high temperature environment ranges from 700° C. to 1,100° C.; the optimal temperature for growing carbon nanotubes with multiple junctions is around 800° C.

The carbon nanotubes are 2D structures such as L-junction, Y-junction, T-junction, H-junction, or 3D multiple junctions which form web-like structures.

Specifically, the 3D junctions refer to spatial junctions that can be connected to several different surface planes.

### BRIEF DESCRIPTION OF THE DRAWINGS

FIG. 1 is a 10,000× transmission electron microscopy (TEM) image showing the growth of carbon nanotubes on a substrate according to the current invention.

FIG. 2 is a 20,000× TEM image (combined from two images) showing the growth of carbon nanotubes with H-junction or multiple Y-junctions according to the current invention.

FIG. 3 is an 80,000× TEM image showing the growth of carbon nanotubes with 3D branching structures according to the current invention.

### DETAILED DESCRIPTION OF THE INVENTION

A method contemplated by the invention described herein is the use of simple thermal CVD without any template for fabricating carbon nanotubes with 2D structures such as H-junction and 3D multiple junctions. The method comprises of supplying at least one substrate, metal powders, and carbon-containing reactant gas to CVD system under high temperature. Carbon nanotubes with multiple junctions form above the substrate demonstrating 2D or 3D web-like structures of uniform diameters.

Detailed description of the fabrication the carbon nanotubes is as follows:

First, a suitable substrate which the carbon nanotubes will grow on is chosen and prepared. The preparation process includes steps such as rubbing the surface of the substrate against sandpaper and cleaning it ultrasonically. Next, the processed substrate is placed in a thermal CVD system. A ceramic container carrying metal powders as catalyst source is positioned at a distance above the substrate. This arrangement allows evaporation-deposition of the metal powders to occur at a certain temperature such that nano-scale metal catalysts are seeded on the substrate.

In addition, carbon-containing reactant gas is fed into a reactor inside the thermal CVD system, which provides sufficient energy for pyrolysis of the gas and formation of carbon nanotubes having multiple junctions on the substrate.

There is no restriction as to the type of substrate that may be used in this invention; however, silicon, especially single-crystalline silicon, is suitable for the growth carbon nanotubes.

The metal is either a type of transition metal or its alloy. Suitable transition metals are: iron, cobalt, nickel, platinum, palladium, and/or compounds of these metals, and/or alloys thereof. In particular, iron is well suited for the purpose.

The carbon-containing reactant gas is composed of hydrocarbons. Methane, ethylene, propane, acetylene, or mixtures thereof are all suitable reactant gases. Among these gases, methane is the preferred choice.

The high temperature environment ranges from 700° C. to 1,100° C.; the optimal temperature for growing carbon nanotubes with multiple junctions is 800° C.

The carbon nanotubes are 2D structures such as L-junction, Y-junction, T-junction, H-junction, or 3D multiple junctions which form web-like structures. Nanotubes produced according to the method of this invention exhibit fairly uniform diameters. The 3D junctions refer to spatial junctions that can be connected to several different surface planes.

Hereinafter, an example of the present invention will be explained along with figures that illustrate the advantages and uniqueness of this invention.

### Embodiment

Single-crystalline silicon wafers were chosen as the substrate. It was first scratched with 600-grit sandpaper, washed ultrasonically, and placed in a horizontal tube inside the thermal CVD furnace. A ceramic container with metal powders as the catalyst source was positioned 5 cm above the substrate. Under such arrangement, evaporation-deposition of the metal powders occurred at a certain temperature such that nano-scale metal catalysts were seeded on the substrate. Lastly, methane that had gone through pyrolysis at 800° C. in the thermal CVD system formed carbon nanotubes with multiple junctions under catalyst reactions. This method can be used in an environment with constant pressure; unlike previous methods, it does not require a low pressure environment.

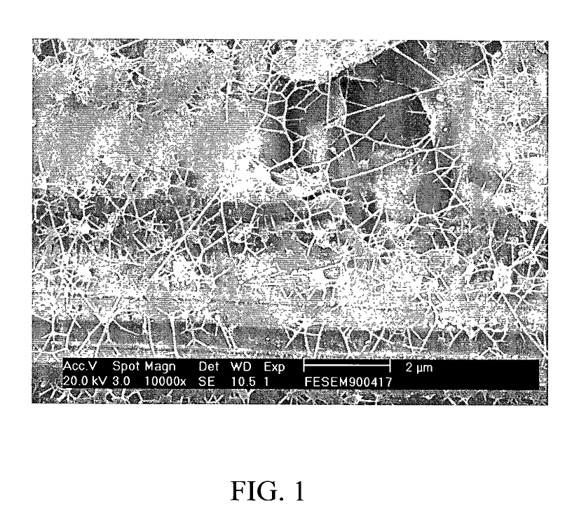

FIG. 1 depicts a 10,000× TEM image of carbon nanotubes growing on a substrate according to the current invention. The figure shows that webs of carbon nanotubes can be produced and that, unlike prior methods, this invention not only allows the growth of carbon nanotubes with Y-junction but also other types of junction such as H-junction (2D) and 3D carbon nanotubes.

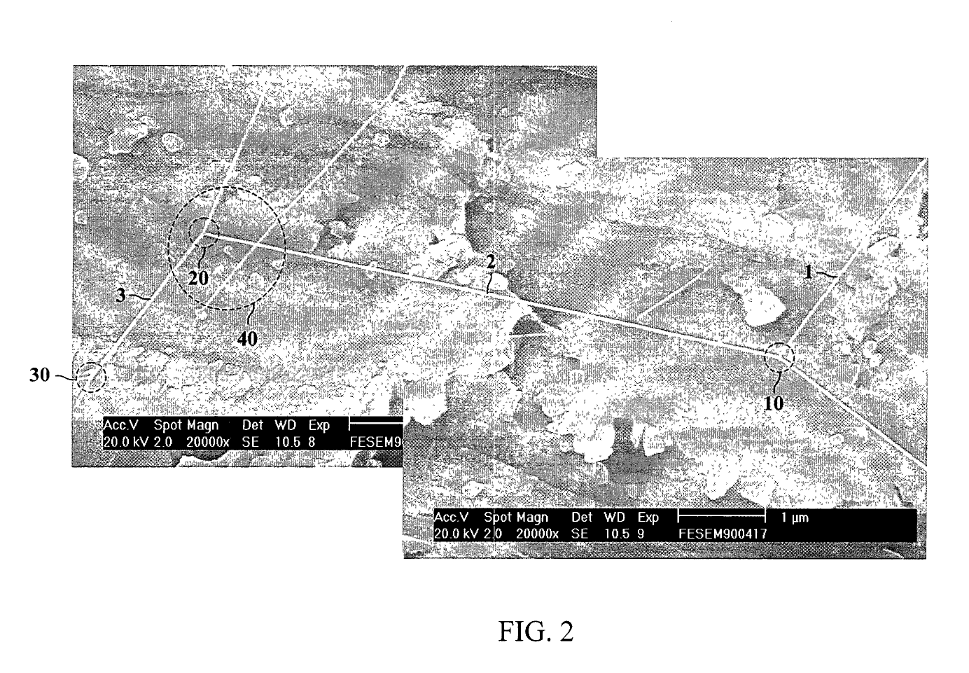

FIG. 2 depicts a 20,000× TEM image (combined by two images) of carbon nanotubes with multiple Y-junctions (10, 30) or H-junction (40). As illustrated in the figure, carbon nanotube (1) is a parent stem grown from catalysts. Along the nanotube (1), it splits into a Y-junction (10) and one of the branches becomes a parent stem as well. The new parent stem continues to split into another Y-junction or nearly a T-junction (20). The carbon nanotube (3) on the bottom left is a branch from the Y-junction in carbon nanotube (2). It becomes a parent stem and splits into another Y-junction. Through this process of continuously splitting or branching, carbon nanotube structures will no longer be limited to 2D but also spread in a 3D fashion.

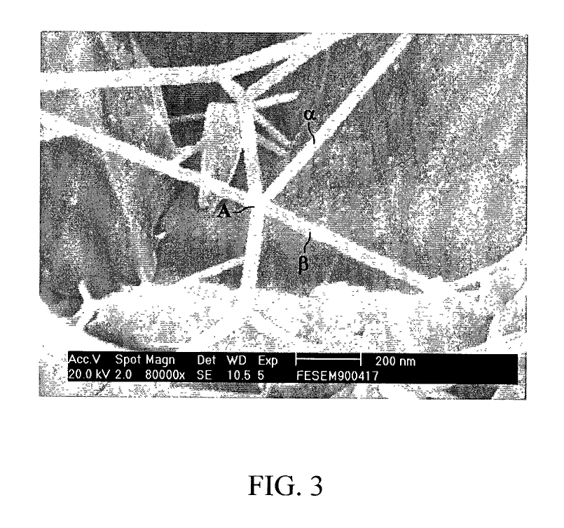

FIG. 3 depicts an 80,000× TEM image showing the growth of carbon nanotubes with 3D branching structures. The center point (A) is connected to five carbon nanotubes. Branches α and β form a Y-junction away from the center point (A). One of the branches in the upper Y-junction (α) further becomes another Y-junction. Based on this process of continuously splitting carbon nanotubes, 3D branching structures can be created. These kinds of structures can be connected to different surface planes such as top and bottom layers.

According to the current invention, carbon nanotubes exhibit uniform diameters. In this embodiment, the carbon nanotubes have diameters ranging from 30 nm to 50 nm.

Using simple thermal CVD method, new 2D and 3D branching structures of carbon nanotubes with uniform diameters can be fabricated. The synthesis of connections between two or more carbon nanotubes is a crucial step in the development of carbon-nanotube-based circuits. Basic nano-device elements including p-n junction in diodes, heterojunction in transistors, and metal-oxide-semiconductors, all need such connections. The formation of 2D H-junction and multiple Y-junctions, and 3D branching structures, not only shows the possibility of realizing complex 3D carbon nanotube structures but also provides the nanotechnology community with new base materials for the development of nano-scale mechanical and electrical devices, such as fundamental nano-scale junctions and quantum wires.

While in the foregoing method this invention has been described in relation to certain preferred embodiments thereof, it will be apparent to those skilled in the art that the above embodiments may be altered in many ways without departing from the scope of the invention. Accordingly, the scope of the invention should be determined by the following claims and their legal equivalents.

This invention provides an approach for fabricating carbon nanotubes with both 2D and 3D branching structures. Compared to the previous techniques which can only produce 2D structures, this invention has achieved a progressive breakthrough. Carbon nanotubes fabricated using this new approach are useful for applications in optic-electronic devices, electronic devices, biomedical science, and energy resource, which increase the overall human benefits.

1. A method for fabrication of carbon nanotubes having multiple junctions, comprising:
in a chemical vapor deposition (CVD) system, providing at least:
a substrate;
metal powders; and
carbon-containing reactant gas whereby under high temperature carbon nanotubes with multiple junctions, specifically two-dimensional and/or three-dimensional web-like structures of uniform diameters, are formed on the substrate.

2. The method of claim 1, wherein no template is required.

3. The method of claim 1, wherein silicon is the preferred substrate.

4. The method of claim 3, wherein single-crystalline silicon is the preferred silicon.

5. The method of claim 1, wherein the metals are transition metals or alloys thereof.

6. The method of claim 5, wherein preferred transition metals are: iron, cobalt, nickel, platinum, palladium, and/or compounds of these metals, and/or alloys thereof.

7. The method of claim 6, wherein the preferred metal is iron.

8. The method of claim 1, wherein the metal powders are seeded on the substrate using evaporation-deposition method.

9. The method of claim 1, wherein the carbon-containing reactant gas is composed of hydrocarbons.

10. The method of claim 9, wherein the hydrocarbons can be methane, ethylene, propane, acetylene, or mixtures thereof.

11. The method of claim 10, wherein the preferred hydrocarbon is methane.

12. The method of claim 1, wherein the high-temperature environment varies from 700° C. to 1,100° C.

13. The method of claim 12, wherein the preferred temperature is 800° C.

14. The method of claim 1, wherein the two-dimensional carbon nanotube structures are L-junction, Y-junction, T-junction, or H-junction.

15. The method of claim 1, wherein the three-dimensional branching junctions refer to spatial junctions that can be connected to several different surface planes.
